(19) United States
(12) Patent Application Publication
(10) Pub. No.: US 2023/0049363 A1
(43) Pub. Date: Feb. 16, 2023

(54) SEMICONDUCTOR DEVICE AND METHOD OF MANUFACTURING SEMICONDUCTOR DEVICE

(71) Applicant: SUMITOMO ELECTRIC INDUSTRIES, LTD., Osaka (JP)

(72) Inventor: Yukihiro TSUJI, Osaka (JP)

(21) Appl. No.: 17/813,696

(22) Filed: Jul. 20, 2022

(30) Foreign Application Priority Data
Aug. 16, 2021 (JP) 2021-132428

(51) Int. Cl. H01L 29/66; H01L 29/20; H01L 29/778; H01L 29/47

(52) U.S. Cl. CPC H01L 29/66462; H01L 29/2003; H01L 29/7786; H01L 29/475

(57) ABSTRACT

A semiconductor device includes a substrate including a first main surface; a semiconductor layer provided on the first main surface of the substrate; an electrically insulating layer provided on the semiconductor layer; a source electrode and a drain electrode that are provided on the semiconductor layer; and a gate electrode provided on the electrically insulating layer. The semiconductor layer has an electron transport layer provided on the substrate and including a first upper surface, and has an electron supply layer provided on the electron transport layer. A first opening and a second opening are each formed in the electron supply layer and the electron transport layer. A third opening connected to the first opening and a fourth opening connected to the second opening are each formed in the electrically insulating layer.

### CROSS-REFERENCE TO RELATED APPLICATIONS

This application claims priority to Japanese Patent Application No. 2021-132428, filed on Aug. 16, 2021, the entire contents of which are incorporated herein by reference.

### TECHNICAL FIELD

The present disclosure relates to a semiconductor device and a method of manufacturing the semiconductor device.

### BACKGROUND

For high electron mobility transistors (HEMTs), methods have been proposed to reduce contact resistance, which is the sum of resistance between a source electrode and two-dimensional electron gas (2DEG) and resistance between a drain electrode and 2DEG. In this method, an opening is formed in an electron supply layer and an electron transport layer, a GaN (n⁺ GaN) layer containing an n-type impurity at a high concentration is regrown in the opening, and the source electrode and the drain electrode are formed on the n⁺ GaN layer (regrown layer).
[Patent Document 1] Japanese Unexamined Patent Application Publication No. 2019-125600
[Patent Document 2] U.S. Pat. No. 9,515,161

### SUMMARY

A semiconductor device includes a substrate including a first main surface and a semiconductor layer provided on the first main surface of the substrate, the semiconductor layer including an electron transport layer provided on the substrate. The electron transport layer includes a first upper surface, an electron supply layer provided on the electron transport layer, a source region containing a first electrically conductive impurity, the source region being provided in a first opening, and a drain region containing the first electrically conductive impurity, the drain region being provided in a second opening. The semiconductor device includes an electrically insulating layer provided on the semiconductor layer. The semiconductor device includes a source electrode and a drain electrode, each of the source electrode and the drain electrode being provided on the semiconductor layer, the source electrode being provided on the source region, and the drain electrode being provided on the drain region. The semiconductor device includes a gate electrode provided on the electrically insulating layer. The first opening and the second opening are each formed in the electron supply layer and the electron transport layer, the first opening having a first edge toward the second opening, the second opening having a second edge toward the first opening. A bottom of the first opening and a bottom of the second opening are positioned lower than the first upper surface, so as to be toward the substrate. A third opening connected to the first opening, and a fourth opening connected to the second opening are each formed in the electrically insulating layer, the third opening having a third edge toward the fourth opening, and the fourth opening having a fourth edge toward the third opening. In a plan view viewed in a direction perpendicular to the first main surface, the first edge of the first opening is positioned closer to the second opening than the third edge of the third opening is. The second edge of the second opening is positioned closer to the first opening than the fourth edge of the fourth opening is. A portion of the source region overlaps the electrically insulating layer. A portion of the drain region overlaps the electrically insulating laver.

### BRIEF DESCRIPTION OF THE DRAWINGS

FIG. 1 is a cross-sectional view illustrating a semiconductor device according to a first embodiment.

FIG. 2 is a cross-sectional view (part 1) illustrating the semiconductor device according to the first embodiment, the view being described for a method of manufacturing the semiconductor device.

FIG. 3 is a cross-sectional view (part 2) illustrating the semiconductor device according to the first embodiment, the view being described for the method of manufacturing the semiconductor device.

FIG. 4 is a cross-sectional view (part 3) illustrating the semiconductor device according to the first embodiment, the view being described for the method of manufacturing the semiconductor device.

FIG. 5 is a cross-sectional view (part 4) illustrating the semiconductor device according to the first embodiment, the view being described for the method of manufacturing the semiconductor device.

FIG. 6 is a cross-sectional view (part 5) illustrating the semiconductor device according to the first embodiment, the view being described for the method of manufacturing the semiconductor device.

FIG. 7 is a cross-sectional view (part 6) illustrating the semiconductor device according to the first embodiment, the view being described for the method of manufacturing the semiconductor device.

FIG. 8 is a cross-sectional view (part 7) illustrating the semiconductor device according to the first embodiment, the view being described for the method of manufacturing the semiconductor device.

FIG. 9 is a cross-sectional view (part 8) illustrating the semiconductor device according to the first embodiment, the view being described for the method of manufacturing the semiconductor device.

FIG. 10 is a cross-sectional view (part 9) illustrating the semiconductor device according to the first embodiment, the view being described for the method of manufacturing the semiconductor device.

FIG. 11 is a cross-sectional view (part 10) illustrating the semiconductor device according to the first embodiment, the view being described for the method of manufacturing the semiconductor device.

FIG. 12 is a cross-sectional view (part 1) illustrating a semiconductor device according to a reference example, the view being described for the method of manufacturing the semiconductor device.

FIG. 13 is a cross-sectional view (part 2) illustrating the semiconductor device according to the reference example, the view being described for the method of manufacturing the semiconductor device.

FIG. 14 is a cross-sectional view (part 3) illustrating the semiconductor device according to the reference example, the view being described for the method of manufacturing the semiconductor device.

FIG. 15 is a cross-sectional view (part 4) illustrating the semiconductor device according to the reference example, the view being described for the method of manufacturing the semiconductor device.

FIG. 16 is a cross-sectional view (part 1) illustrating the semiconductor device according to a first modification of the first embodiment, the view being described for the method of manufacturing the semiconductor device.

FIG. 17 is a cross-sectional view (part 2) illustrating the semiconductor device according to the first modification of the first embodiment, the view being described for the method of manufacturing the semiconductor device.

FIG. 18 is a cross-sectional view (part 1) illustrating the semiconductor device according to the second modification of the first embodiment, the view being described for the method of manufacturing the semiconductor device.

FIG. 19 is a second cross-sectional view illustrating the semiconductor device according to the second modification of the first embodiment, the view being described for the method of manufacturing the semiconductor device.

FIG. 20 is a cross-sectional view illustrating a semiconductor device according to the second embodiment.

FIG. 21 is a cross-sectional view (part 1) illustrating the semiconductor device according to the second embodiment, the view being described for the method of manufacturing the semiconductor device.

FIG. 22 is a cross-sectional view (part 2) illustrating the semiconductor device according to the second embodiment, the view being described for the method of manufacturing the semiconductor device.

FIG. 23 is a cross-sectional view (part 3) illustrating the semiconductor device according to the second embodiment, the view being described for the method of manufacturing the semiconductor device.

### DESCRIPTION OF EMBODIMENTS

Related art information relevant to the present disclosure recognized by the inventor of this application will be provided below. When openings and regrowth layers are formed by conventional methods, it may be difficult to control the shape of the regrowth layers.

An object of the present disclosure is to provide a semiconductor device and a method of manufacturing the semiconductor device in which the shape of a regrowth layer is easily controlled.

### Description of Embodiments of Present Disclosure

Embodiments of the present disclosure are first listed and described as follows.

(1) A semiconductor device includes a substrate including a first main surface and a semiconductor layer provided on the first main surface of the substrate, the semiconductor layer including an electron transport layer provided on the substrate. The electron transport layer includes a first upper surface, an electron supply layer provided on the electron transport layer, a source region containing a first electrically conductive impurity, the source region being provided in a first opening, and a drain region containing the first electrically conductive impurity, the drain region being provided in a second opening. The semiconductor device includes an electrically insulating layer provided on the semiconductor layer. The semiconductor device includes a source electrode and a drain electrode, each of the source electrode and the drain electrode being provided on the semiconductor layer, the source electrode being provided on the source region, and the drain electrode being provided on the drain region. The semiconductor device includes a gate electrode provided on the electrically insulating layer. The first opening and the second opening are each formed in the electron supply layer and the electron transport layer, the first opening having a first edge toward the second opening, the second opening having a second edge toward the first opening. A bottom of the first opening and a bottom of the second opening are positioned lower than the first upper surface, so as to be toward the substrate. A third opening connected to the first opening, and a fourth opening connected to the second opening are each formed in the electrically insulating layer, the third opening having a third edge toward the fourth opening, and the fourth opening having a fourth edge toward the third opening. In a plan view viewed in a direction perpendicular to the first main surface, the first edge of the first opening is positioned closer to the second opening than the third edge of the third opening is. The second edge of the second opening is positioned closer to the first opening than the fourth edge of the fourth opening is. A portion of the source region overlaps the electrically insulating layer. A portion of the drain region overlaps the electrically insulating laver.

In the plan view, the first edge of the first opening is positioned closer to the second opening than the third edge of the third opening is, and the second edge of the second opening is positioned closer to the first opening than the fourth edge of the fourth opening is. A portion of the source region overlaps the electrically insulating layer, and a portion of the drain region overlaps the electrically insulating layer. Therefore, when the source region and the drain region are formed as regrowth layers, generation of an abnormal growth portion described later is suppressed, and thus shapes of the source region and the drain region are easily controlled.

(2) In (1), in a plan view viewed in the direction perpendicular to the first main surface, a distance between the first edge and the third edge may be greater than or equal to 0.2 μm and less than or equal to 1.5 μm, and a distance between the second edge and the fourth edge may be greater than or equal to 0.2 μm and less than or equal to 1.5 μm. When each of the distances is greater than or equal to 0.2 μm and less than or equal to 1.5 μm, shapes of the source region and the drain region can be more easily controlled.

(3) In (1) or (2), a portion of an upper surface of the source region may be in contact with a portion of a lower surface of the electrically insulating layer, and a portion of an upper surface of the drain region may be in contact with another portion of the lower surface of the electrically insulating layer In this case, it is easier to control the shapes of the source region and the drain region, by regrowth.

(4) In any one of (1) to (3), the gate electrode may be in Schottky contact with the semiconductor layer. In this case, a high-speed operation is enabled as compared with a case where an MIS type gate structure is used.

(5) A method of manufacturing a semiconductor device includes forming an electron transport layer including a first upper surface, the electron transport being situated on a first main surface of a substrate. The method includes forming an electron supply layer on the electron transport layer; forming an electrically insulating layer above the electron supply layer. The method forming a third opening and a fourth opening in the electrically insulating layer, the third opening having a third edge toward the fourth opening, and the fourth opening having a fourth edge toward the third opening. The method includes forming (i) a first opening connected to the third opening and (ii) a second opening connected to the fourth opening, each of the first opening and the second opening being formed in the electron supply layer and the electron transport layer, the first opening having a first edge toward the second opening, and the second opening having a second edge toward the first opening. The method includes forming a source region containing a first electrically conductive impurity in the first opening and forming a drain region containing the first electrically conductive impurity in the second opening. The method includes forming a source electrode on the source region and forming a drain electrode on the drain region. The method includes forming a gate electrode on the electrically insulating layer. A bottom of the first opening and a bottom of the second opening are positioned lower than the first upper surface, so as to be toward the substrate. In a plan view viewed in a direction perpendicular to the first main surface, the first edge of the first opening is positioned closer to the second opening than the third edge of the third opening is, and the second edge of the second opening is positioned closer to the first opening than the fourth edge of the fourth opening is. A portion of the source region overlaps the electrically insulating layer, and a portion of the drain region overlaps the electrically insulating layer.

In the plan view, the first edge of the first opening is positioned closer to the second opening than the third edge of the third opening is, and the second edge of the second opening is positioned closer to the first opening than the fourth edge of the fourth opening is. Therefore, when the source region and the drain region are formed by regrowth, generation of an abnormal growth portion described later is suppressed, and thus the shapes of the source region and the drain region are easily controlled.

(6) In (5), A method of manufacturing the semiconductor device may further include forming a mask on the electrically insulating layer, between the forming of the electrically insulating layer and the forming of the third opening and the fourth opening. The forming of the third opening and the fourth opening includes performing reactive ion etching of the electrically insulating layer, by using the mask. The forming of the first opening and the second opening includes performing photoelectrochemical etching of the electron supply layer and the electron transport layer, by using the mask. It is easy to form the first opening and the second opening having desired shapes by photoelectrochemical etching.

(7) In (5), the method may include forming a mask on the electrically insulating layer between forming the electrically insulating layer and forming the third opening and the fourth opening.

Forming the third opening and the fourth opening may include performing reactive ion etching of the electrically insulating layer by using the mask. Forming the first opening and the second opening may include performing reactive ion etching of the electron supply layer and the electron transport layer by using the mask. In the reactive ion etching of the electron supply layer and the electron transport layer, supply of a reactive gas is continued after the first main surface of the substrate is exposed. By continuing the supply of the reactive gas after the first main surface of the substrate is exposed, it is easy to form a first opening and a second opening having desired shapes.

### Details of Embodiments of Present Disclosure

Hereinafter, embodiments of the present disclosure will be described in detail, but the present disclosure is not limited thereto. In the specification and the drawings, components having substantially the same functional configuration are denoted by the same reference signs, and accordingly, redundant description thereof may be omitted. In a crystallographic description in the specification, an individual orientation is represented by [ ], an aggregate orientation is represented by < >, an individual plane is represented by ( ) and an aggregate plane is represented by { }. A negative crystallographic index is generally expressed by placing “−” (bar) on top of a number, but in this specification, a negative sign is placed before the number.

### First Embodiment

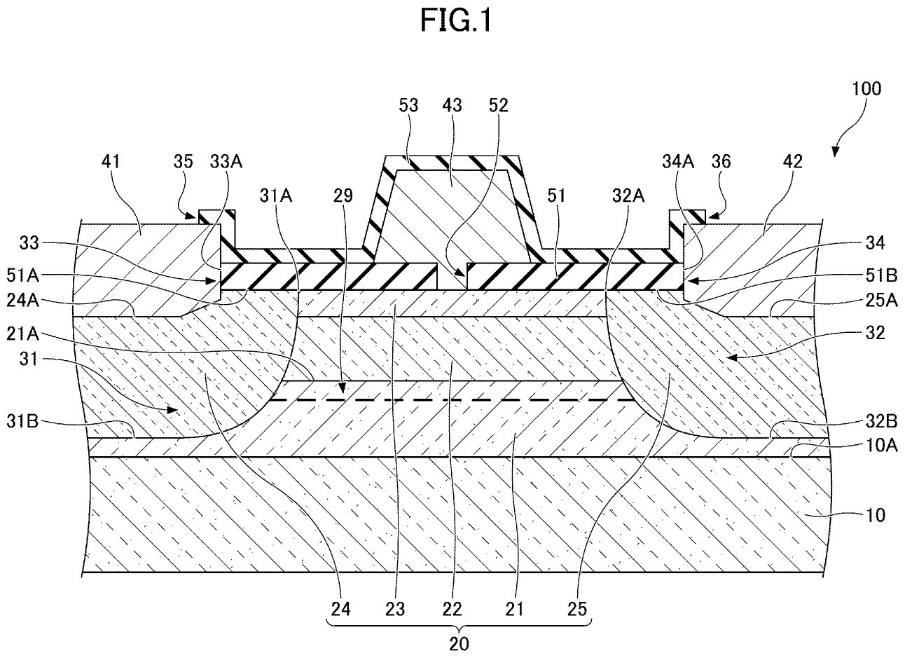

A first embodiment will be described. The first embodiment relates to a semiconductor device including a GaN-HENT having a nitride semiconductor that is used as a main constituent material. FIG. 1 is a cross-sectional view illustrating a semiconductor device according to the first embodiment.

As illustrated in FIG. 1, a semiconductor device 100 according to the first embodiment includes a substrate 10 having a first main surface 10A, and includes a layered structure 20 of a plurality of semiconductor layers that are provided on the first main surface 10A. The substrate 10 is an SiC substrate having, for example, a (0001) principal surface as the first main surface 10A, and a stacking direction of the layered structure 20 is, for example, a [0001] direction. The layered structure 20 includes an electron transport layer 21, an electron supply layer 22, and a cap layer 23 that are sequentially formed, when viewed from the substrate 10. The electron transport layer 21 is, for example, an undoped GaN layer which has a thickness of about 1000 nm. The electron supply layer 22 is, for example, an n-type AlGaN layer which has a thickness of about 20 nm. The cap layer 23 is, for example, an n-type GaN layer, which has a thickness of about 5 nm. An n-type impurity used in the present embodiment is, for example, Si or Ge. The layered structure 20 may include a buffer layer (not illustrated) between the electron transport layer 21 and the substrate 10. The buffer layer is, for example, an AlN layer. The layered structure 20 is an example of a semiconductor layer.

A first opening 31 used for a source, and a second opening 32 used for a drain are formed in the layered structure 20. A bottom 31B of the first opening 31 and a bottom 32B of the second opening 32 are positioned lower than an upper surface 21A of the electron transport layer 21, so as to be disposed toward the substrate 10. In other words, the first opening 31 and second opening 32 are formed lower than the upper surface 21A of the electron transport layer 21. The first opening 31 and the second opening 32 do not reach the substrate 10, and the bottom 31B of the first opening 31 and the bottom 32B of the second opening 32 are each spaced apart from the substrate 10. The bottom 31B of the first opening 31 and the bottom 32B of the second opening 32 are positioned closer to the first main surface 10A than the upper surface 21A of the electron transport layer 21 is. The upper surface 21A is an example of a first upper surface.

The semiconductor device 100 includes an electrically insulating layer 51 provided on the layered structure 20. The electrically insulating layer 51 is, for example, a Si nitride layer or an Al oxide layer. A third opening 33 used for the source and a fourth opening 34 used for the drain are formed in the electrically insulating layer 51. The third opening 33 is connected to the first opening 31, and the fourth opening 34 is connected to the second opening 32.

The first opening 31 has a first edge 31A toward the second opening 32, and the second opening 32 has a second edge 32A toward the first opening 31. The third opening 33 has a third edge 33A toward the fourth opening 34, and the fourth opening 34 has a fourth edge 34A toward the third opening 33. In a plan view viewed in a direction perpendicular to the first main surface 10A, the first edge 31A of the first opening 31 is positioned closer to the second opening 32 than the third edge 33A of the third opening 33 is, and the second edge 32A of the second opening 32 is positioned closer to the first opening 31 than the fourth edge 34A of the fourth opening 34 is. In other words, the electrically insulating layer 51 has a portion that is an overhang for each of the first opening 31 and the second opening 32. The electrically insulating layer 51 extends in a direction away from the second opening 32 such that a given end of the electrically insulating layer is disposed outside the first edge 31A of the first opening 31. The electrically insulating layer 51 also extends in a direction away from the first opening 31 such that a given end of the electrically insulating layer is disposed outside the second edge 32A of the second opening 32.

The layered structure 20 has a source region 24 provided in the first opening 31. The source region 24 is provided on the bottom 31B of the first opening 31. In the plan view viewed in the direction perpendicular to the first main surface 10A, a portion of the source region 24 overlaps the electrically insulating layer 51. A part of an upper surface 24A of the source region 24 is in contact with a lower surface 51A of the portion of the electrically insulating layer 51 that extends toward the first opening 31. For example, the lower surface 51A of the portion of the electrically insulating layer 51 that extends toward the first opening 31 is covered by the source region 24. Another part of the upper surface 24A of the source region 24 may be positioned closer to the first main surface 10A of the substrate 10 than the lower surface 51A of the portion of the electrically insulating layer 51 that extends toward the first opening 31 is. The source region 24 is, for example, an n-type GaN layer. The source region 24 contains, for example, an n-type impurity at a higher concentration than the electron supply layer 22. That is, the electron supply layer 22 contains the n-type impurity at a lower concentration than the source region 24. Therefore, the electric resistance of the source region 24 is lower than that of the electron supply layer 22. The n-type impurity concentration of the source region 24 is, for example, greater than or equal to 5×10 cm⁻³ and less than or equal to 2×10¹⁹ cm⁻³.

The layered structure 20 has a drain region 25 provided in the second opening 32. The drain region 25 is provided on the bottom 32B of the second opening 32. In the plan view viewed in the direction perpendicular to the first main surface 10A, a portion of the drain region 25 overlaps the electrically insulating layer 51. A part of an upper surface 25A of the drain region 25 is in contact with the lower surface 51B of the portion of the electrically insulating layer 51 that extends toward the second opening 32. For example, the lower surface 51B of the portion of the electrically insulating layer 51 that extends toward the second opening 32 is covered by the drain region 25. Another part of the upper surface 25A of the drain region 25 may be positioned to the first main surface 10A of the substrate 10 than the lower surface 51B of the portion of the electrically insulating layer 51 that extends toward second opening 32 is. The drain region 25 is, for example, an n-type GaN layer. The drain region 25 contains, for example, an n-type impurity at a concentration higher than that of the electron supply layer 22. That is, the electron supply layer 22 contains the n-type impurity at a lower concentration than the drain region 25. Therefore, the electric resistance of the drain region 25 is lower than that of the electron supply layer 22. The n-type impurity concentration of the drain region 25 is, for example, greater than or equal to 5×10¹⁸ cm⁻³ and less than or equal to 2×10¹⁹ cm⁻³.

The semiconductor device 100 includes a source electrode 41 provided on the source region 24, and includes a drain electrode 42 provided on the drain region 25. Each of the source electrode 41 and the drain electrode 42 include, for example, a Ta film and an Al film.

A seventh opening 52 used for the gate is formed in the electrically insulating layer 51, between the source electrode 41 and the drain electrode 42. A portion of the surface of the layered structure 20 is exposed through the seventh opening 52. The semiconductor device 100 includes a gate electrode 43 that contacts the layered structure 20 through the seventh opening 52. The gate electrode 43 includes, for example, a Ni film and an Au film. The gate electrode 43 has, for example, a T-shape, when viewed in cross-section. The gate electrode 43 is in Schottky contact with the layered structure 20. Since the gate electrode 43 is in Schottky contact with the layered structure 20, a high-speed operation is enabled.

The semiconductor device 100 further includes an electrically insulating layer 53 covering the gate electrode 43, the source electrode 41, and the drain electrode 42. The electrically insulating layer 53 is, for example, a Si nitride layer or an Al oxide layer. A fifth opening 35 through which a portion of the source electrode 41 is exposed, and a sixth opening 36 through which a portion of the drain electrode 42 is exposed are formed in the electrically insulating layer 53.

In the semiconductor device 100, a 2DEG 29 is present near the upper surface 21A of the electron transport layer 21. The source electrode 41 is in ohmic contact with the 2DEG 29, through the source region 24, and the drain electrode 42 is in ohmic contact with the 2DEG 29, through the drain region 25. Therefore, the presence of the source region 24 and drain region 25 can reduce the contact resistance, which is the sum of the resistance between the source electrode 41 and the 2DEG 29 and the resistance between the drain electrode 42 and the 2DEG 29.

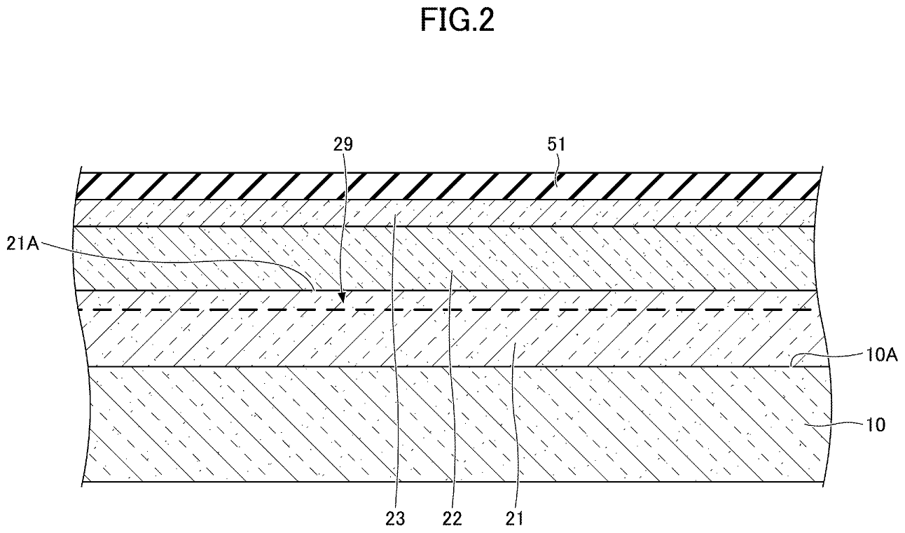

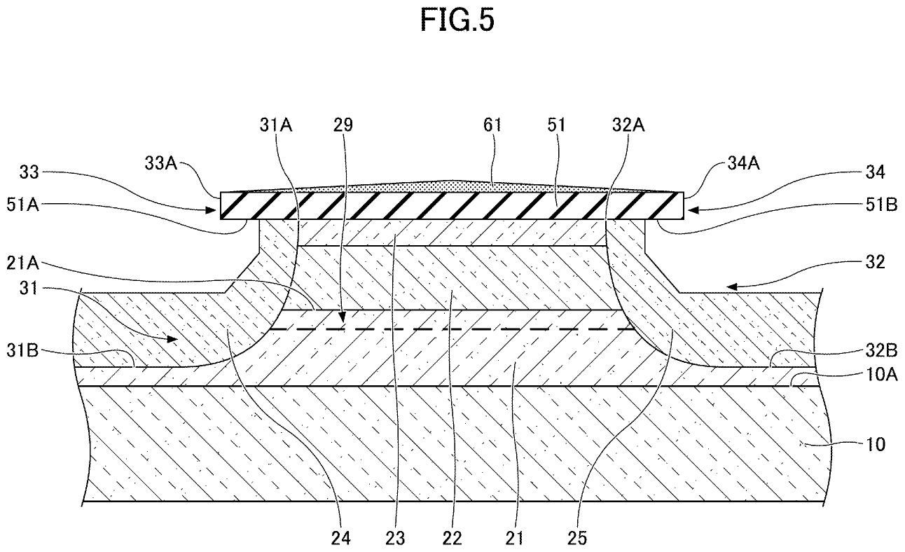

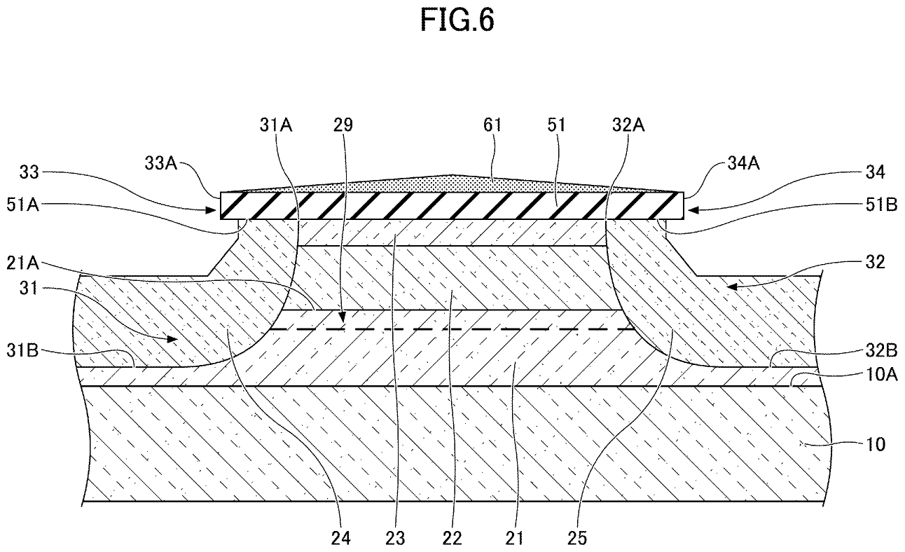

Next, a method of manufacturing the semiconductor device 100 according to the first embodiment will be described. FIGS. 2 to 11 are cross-sectional views illustrating the semiconductor device according to the first embodiment, the views being described for the method of manufacturing the semiconductor device.

As illustrated in FIG. 2, the electron transport layer 21, the electron supply layer 22, and the cap layer 23 are formed on and above the substrate 10. The electron transport layer 21, the electron supply layer 22, and the cap layer 23 are formed by, for example, metal organic chemical vapor deposition (MOCVD). Next, the electrically insulating layer 51 is formed on the cap layer 23. The electrically insulating layer 51 is formed by, for example, chemical vapor deposition (CVD).

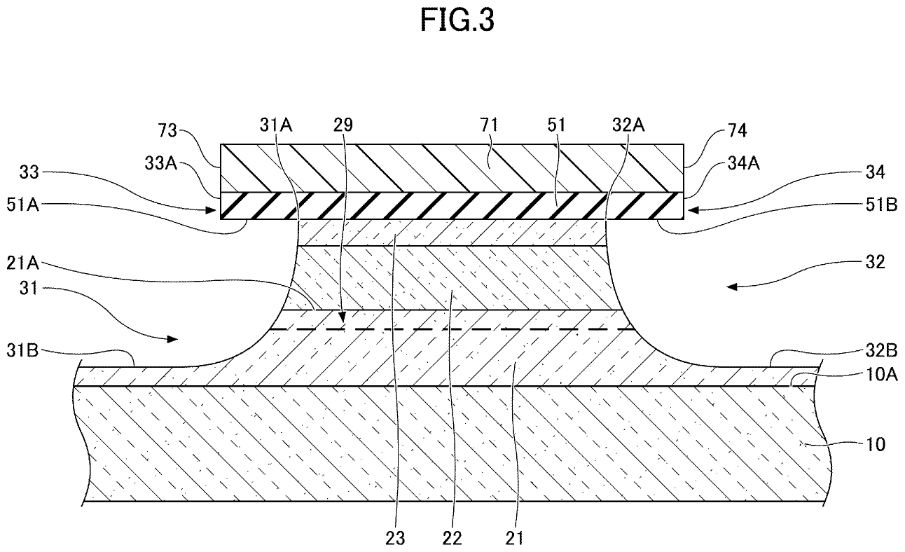

Next, as illustrated in FIG. 3, a resist mask 71 is formed on the electrically insulating layer 51. In the resist mask 71, an opening 73 and an opening 74 are formed. A region where the third opening 33 is formed is exposed through the opening 73, and a region where the fourth opening 34 is formed is exposed through the opening 74. Next, in the electrically insulating layer 51, the third opening 33 is formed through the opening 73 and the fourth opening 34 is formed through the opening 74, by reactive ion etching (RIE). Reactive gas containing fluorine (F) may be used to etch the electrically insulating layer 51. Next, by photoelectrochemical etching, the first opening 31 is formed in the electron transport layer 21, the electron supply layer 22, and the cap layer 23, and the first opening 31 is through the opening 73 and the third opening 33. Further, by photoelectrochemical etching, the second opening 32 is formed through the opening 74 and the fourth opening 34. In the photoelectrochemical etching, the electron transport layer 21, the electron supply layer 22, and the cap layer 23 are isotropically etched. Therefore, the electrically insulating layer 51 extends in the direction away from the second opening 32 such that a given end of the electrically insulating layer is disposed outside the first edge 31A of the first opening 31. Also, the electrically insulating layer 51 extends in the direction away from the first opening 31 such that a given end of the electrically insulating layer is disposed outside the second edge 32A of the second opening 32. In other words, the electrically insulating layer 51 has an overhang portion for each of the first opening 31 and the second opening 32. In the plan view viewed in the direction perpendicular to the first main surface 10A, the first edge 31A of the first opening 31 is closer to the second opening 32 than the third edge 33A of the third opening 33 is, and the second edge 32A of the second opening 32 is closer to the first opening 31 than the fourth edge 34A of the fourth opening 34 is.

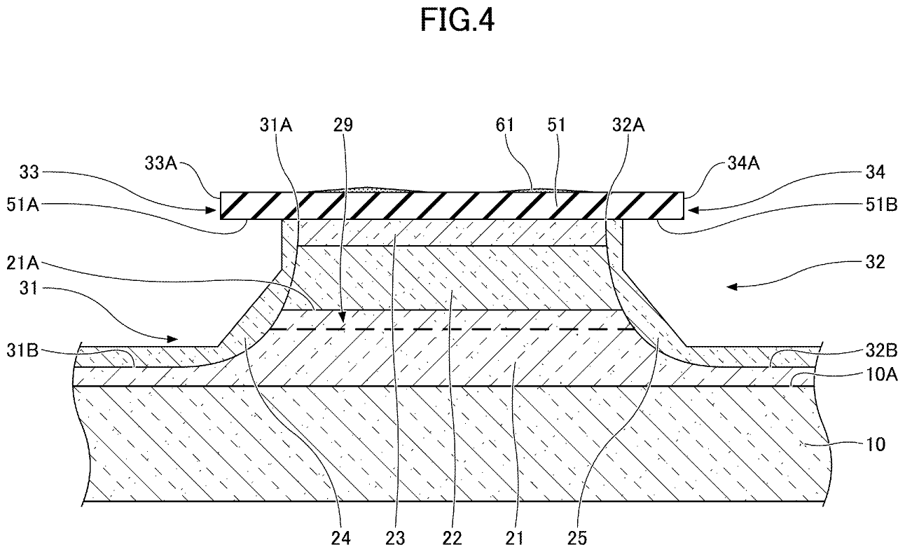

Next, as illustrated in FIGS. 4 to 7, the resist mask 71 is removed to form the source region 24 in the first opening 31 and the drain region 25 in the second opening 32. The source region 24 and the drain region 25 are formed by, for example, MOCVD. FIGS. 4 to 7 illustrate the source region 24 and the drain region 25 that are epitaxially grown in this order. When the source region 24 and the drain region 25 are formed, the temperature of the substrate 10 is set to, for example, about 700° C.

As illustrated in FIGS. 4 to 7, a polycrystalline GaN deposit 61 is accumulated on the electrically insulating layer 51, while the source region 24 and the drain region 25 are epitaxially grown. Although a raw material of Ga (for example, trimethylgallium (TMG)) and a raw material of N (for example, ammonia (NH)) are consumed in the formation of the deposit 61, the deposit 61 is less likely to be formed on the electrically insulating layer 51 than in a case where the deposit is formed on the source region 24 and the drain region 25. Therefore, the source gas supplied to the upper surface of the electrically insulating layer 51 is hardly consumed. The source gas flows toward the third opening 33 or the fourth opening 34, and then is supplied into the first opening 31 or the second opening 32.

GaN that constitutes the source region 24 and the drain region 25 is likely to be epitaxially grown preferentially in a direction inclined from the first main surface 10A, crystallographically. For example, when the first main surface 10A is a C-plane ((0001) plane), a greatest growth rate is obtained in a <11-22> direction that is inclined at about 60 degrees with respect to the first main surface 10A. On the other hand, it is difficult for the raw material gas to reach the portions of the first opening 31 and the second opening 32 that overlap with the overhang portion of the electrically insulating layer 51.

Therefore, when growth rates, which are obtained in (i) the direction perpendicular to the first main surface 10A, (ii) the direction parallel to the first main surface 10A, and (iii) the direction inclined from first main surface 10A, are compared, a lowest growth rate is obtained in the direction parallel to the first main surface 10A. Also, a greatest growth rate is obtained in the direction inclined from the first main surface 10A. For example, a given growth rate obtained in the direction perpendicular to the first main surface 10A is about twice the growth rate obtained in the direction parallel to the first main surface 10A. A given growth rate obtained in the direction inclined from the first main surface 10A is about three times the growth rate obtained in the direction parallel to the first main surface 10A.

The formation of the source region 24 and the drain region 25 is stopped, for example, at a timing at which the entire lower surfaces 51A and 51B of the electrically insulating layer 51 are respectively covered by the source region 24 and the drain region 25. In this case, a portion of the upper surface 24A of the source region 24 may be positioned closer to the first main surface 10A of the substrate 10 than the lower surface 51A of the electrically insulating layer 51 is. The greatest distance of a given portion between the lower surface 51A of the electrically insulating layer 51 and the upper surface 24A of the source region 24, when viewed in the thickness direction of the substrate 10, may be about 100 nm. Similarly, a portion of the upper surface 25A of the drain region 25 may be positioned closer to the first main surface 10A of the substrate 10 than the lower surface 51B of the electrically insulating layer 51 is. The greatest distance of a given portion between the lower surface 51B of the electrically insulating layer 51 and upper surface 25A of drain region 25, when viewed in the thickness direction of the substrate 10, may be about 100 nm.

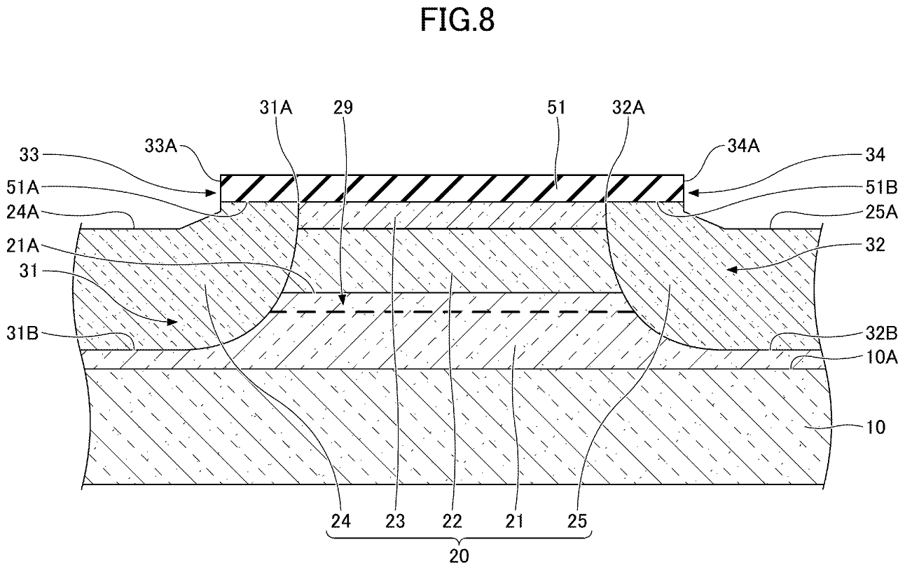

After the source region 24 and the drain region 25 are formed, the deposit 61 on the electrically insulating layer 51 is removed as illustrated in FIG. 8. The deposit 61 can be removed using, for example, tetramethyl ammonium hydroxide (TMAH) with a temperature of about 70° C. The source region 24 and the drain region 25 may be slightly etched by TMAH.

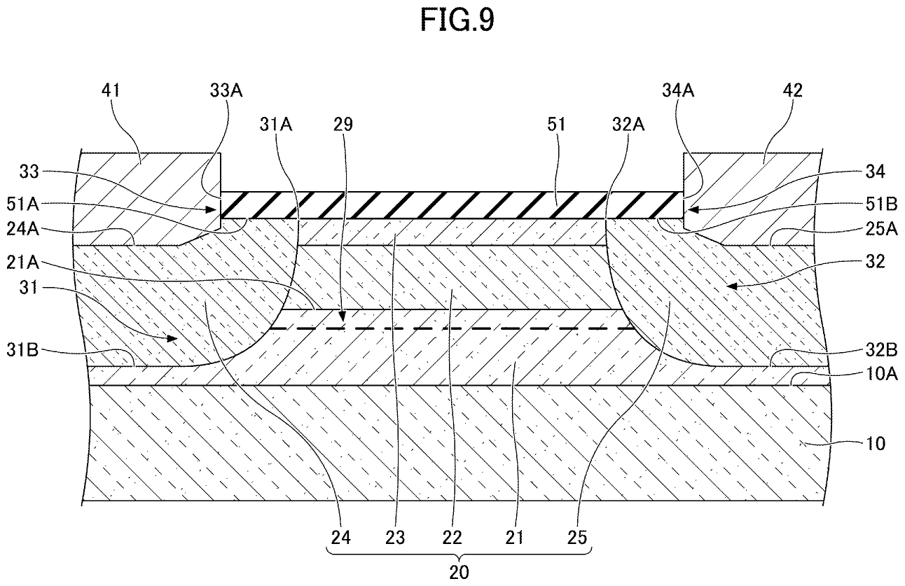

Next, as illustrated in FIG. 9, the source electrode 41 is formed on the source region 24, and the drain electrode 42 is formed on the drain region 25. The source electrode 41 and the drain electrode 42 can be formed by, for example, vapor deposition, a lift-off, and heat treatment for making an alloy. Each of the source electrode 41 and the drain electrode 42 includes, for example, a Ta film and an Al film. The source electrode 41 and the drain electrode 42 are in ohmic contact with the 2DEG 29, via the source region 24 and the drain region 25, respectively.

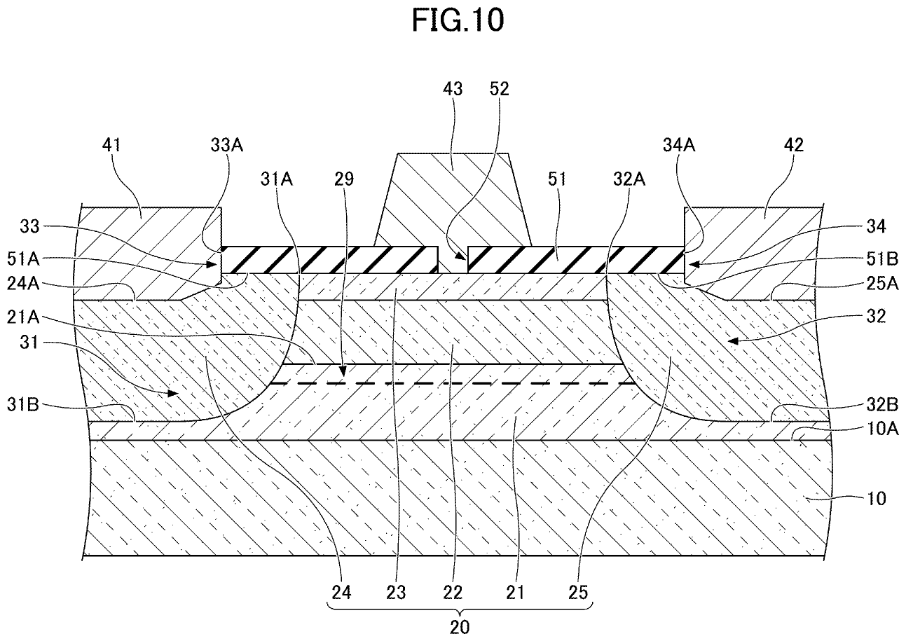

Next, as illustrated in FIG. 10, a seventh opening 52 is formed in the electrically insulating layer 51. In the formation of the seventh opening 52, for example, RIE using a resist mask (not illustrated) is performed. Reactive gas containing F is used for etching of the electrically insulating layer 51. Next, the gate electrode 43 is formed on the electrically insulating layer 51. The gate electrode 43 can be formed by, for example, vapor deposition and a lift-off. The gate electrode 43 includes, for example, a Ni film and an Au film.

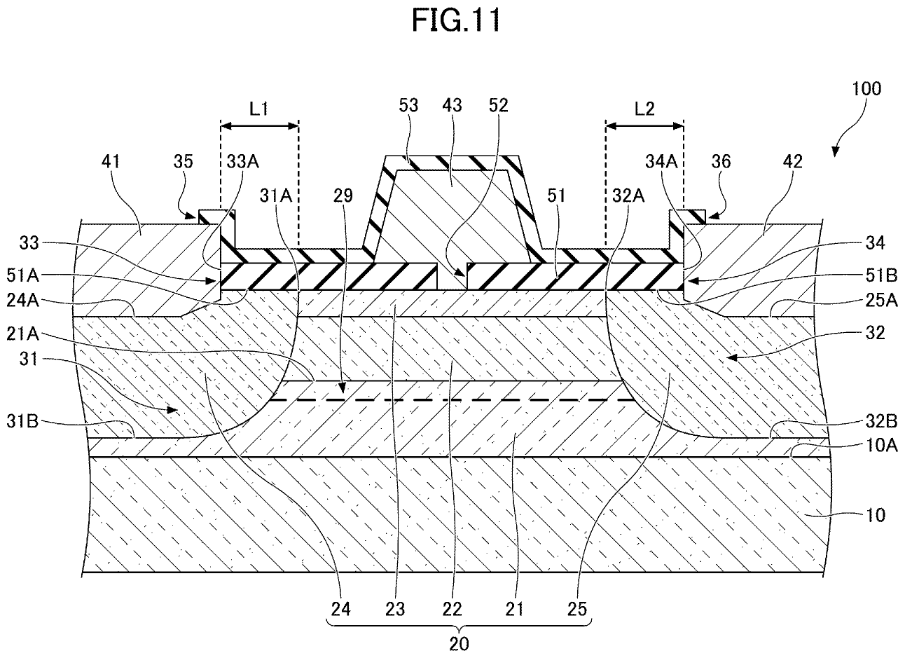

Next, as illustrated in FIG. 11, the electrically insulating layer 53 is formed to cover the gate electrode 43, the source electrode 41, and the drain electrode 42. The electrically insulating layer 53 can be formed by, for example, CVD. Next, the fifth opening 35 through which a portion of the source electrode 41 is exposed, and the sixth opening 36 through which a portion of the drain electrode 42 is exposed are formed in the electrically insulating layer 53. In the formation of the fifth opening 35 and the sixth opening 36, for example, RIE using a resist mask (not illustrated) is performed.

Thereafter, one or more lines and the like are formed as necessary. In this manner, the semiconductor device 100 including a GaN-HEMT can be manufactured.

According to the manufacturing method, in the plan view viewed in the direction perpendicular to the first main surface 10A, the first edge 31A of the first opening 31 is positioned closer to second opening 32 than the third edge 33A of the third opening 33 is, and further, the second edge 32A of the second opening 32 is positioned closer to the first opening 31 than the fourth edge 34A of the fourth opening 34 is. Therefore, when the source region 24 and the drain region 25 are formed as regrowth layers, generation of an abnormal growth portion in a reference example described later is suppressed, and thus the shapes of the source region 24 and the drain region 25 are easily controlled.

In the plan view viewed in the direction perpendicular to the first main surface 10A, a distance L1 between the first edge 31A and the third edge 33A may be greater than or equal to 0.2 μm and less than or equal to 1.5 μm, and a distance L2 between the second edge 32A and the fourth edge 34A may be greater than or equal to 0.2 μm and less than or equal to 1.5 μm. If the distances L1 and L2 are each less than 0.2 μm, it may be difficult to suppress abnormal growth as described later. If the distances L1 and L2 are each greater than 1.5 μm, it may be difficult to adjust an etching amount in photoelectrochemical etching. Each of the distances L1 and L2 may be greater than or equal to 0.5 μm and less than or equal to 1.0 μm, and may be greater than or equal to 0.5 μm and less than or equal to 0.6 μm.

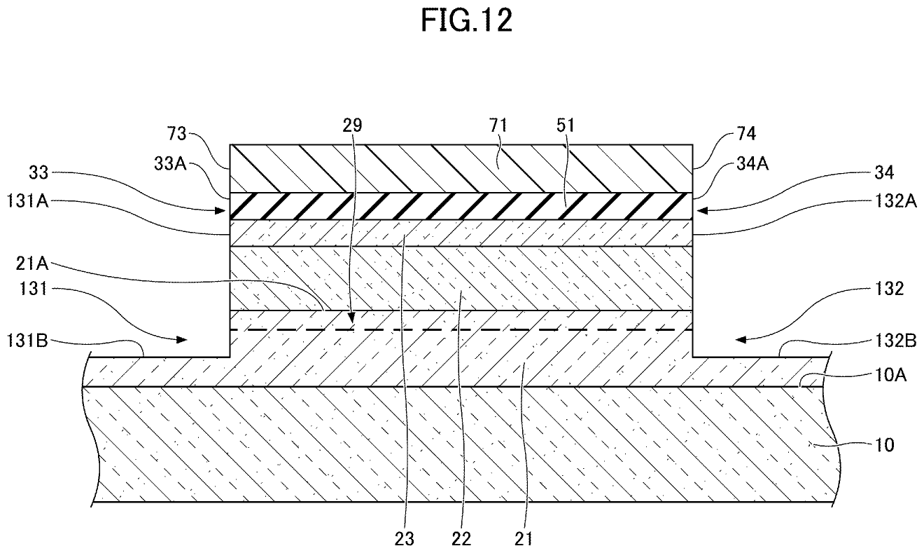

Here, a reference example will be described for comparison with the first embodiment. FIGS. 12 to 15 are cross-sectional views illustrating the semiconductor device according to the reference example, the view being described for the method of manufacturing the semiconductor device.

In the reference example, as illustrated in FIG. 12, processes to form the resist mask 71 are performed in the same manner as that in the first embodiment. Next, the third opening 33 and the fourth opening 34 are formed in the electrically insulating layer 51, by RIE, and further, an opening 131 is formed in each of the electron transport layer 21, the electron supply layer 22, and the cap layer 23, by RIE, and the opening 131 is through the opening 73 and the third opening 33. Also, an opening 132 is formed through the opening 74 and the fourth opening 34. The formation of the openings 131 and 132 is stopped at a middle portion of the electron transport layer 21, and the openings 131 and 132 are each formed so as not to reach the substrate 10. Reactive gas containing chlorine (Cl) is used to etch the electron transport layer 21, the electron supply layer 22, and the cap layer 23.

RIE is anisotropic etching. In this case, in the plan view viewed in the direction perpendicular to the first main surface 10A, the edge 131A of the opening 131 is evenly aligned with the third edge 33A of the third opening 33, and the edge 132A of the opening 132 is coupled to the fourth edge 34A of the fourth opening 34. In other words, unlike the first embodiment, in the electrically insulating layer 51, a portion that is an overhang for each of the first opening 31 and the second opening 32 is not formed. With this arrangement, the bottom 131B and the side surface of the opening 131 are substantially perpendicular to each other, and the bottom 132B and the side surface of the opening 132 are substantially perpendicular to each other.

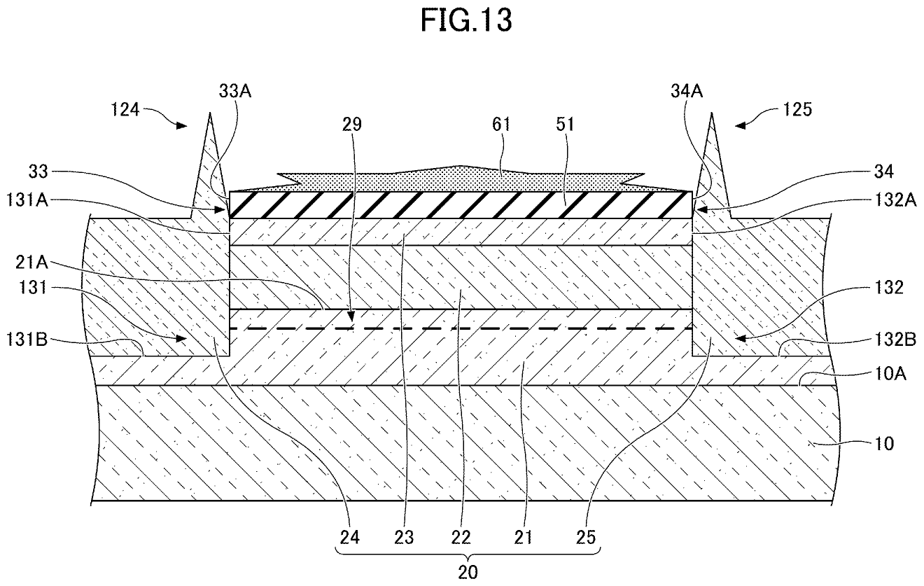

Next, as illustrated in FIG. 13, the resist mask 71 is removed to form the source region 24 in the opening 131 and the drain region 25 in the opening 132. The source region 24 and the drain region 25 are formed by, for example, MOCVD. As in the first embodiment, the polycrystalline GaN deposit 61 is formed on the electrically insulating layer 51, while the source region 24 and the drain region 25 are epitaxially grown.

Also, in the reference example, the raw material gas supplied to the upper surface of the electrically insulating layer 51 is hardly consumed, and thus is supplied to the opening 131 or 132. However, in the reference example, unlike in the first embodiment, the electrically insulating layer 51 does not have a portion that serves as an overhang for each of the openings 131 and 132. Therefore, the source region 24 and the drain region 25 are respectively preferentially grown near the side surfaces of the openings 131 and 132, the source region 24 is grown to include an abnormal growth portion 124 near the electrically insulating layer 51, and the drain region 25 is grown to include an abnormal growth portion 125 near the electrically insulating layer 51. The height of each of the abnormal growth portions 124 and 125 may be about 100 μm.

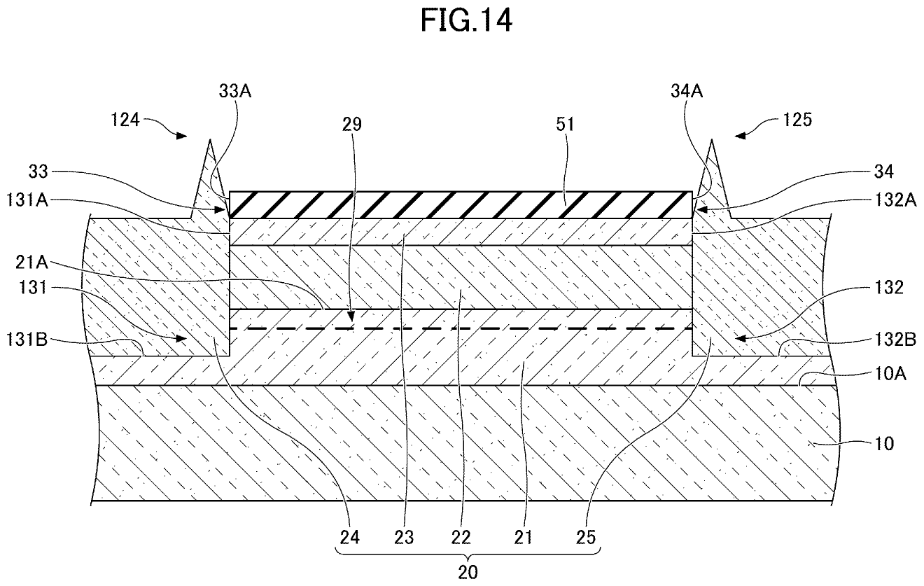

After the source region 24 and the drain region 25 are formed, the deposit 61 on the electrically insulating layer 51 is removed as illustrated in FIG. 14. The deposit 61 can be removed by using, for example, TMAH with a temperature of about 70° C. The abnormal growth portions 124 and 125 may be also etched by TMAH. In this case, the abnormal growth portions 124 and 125 do not disappear.

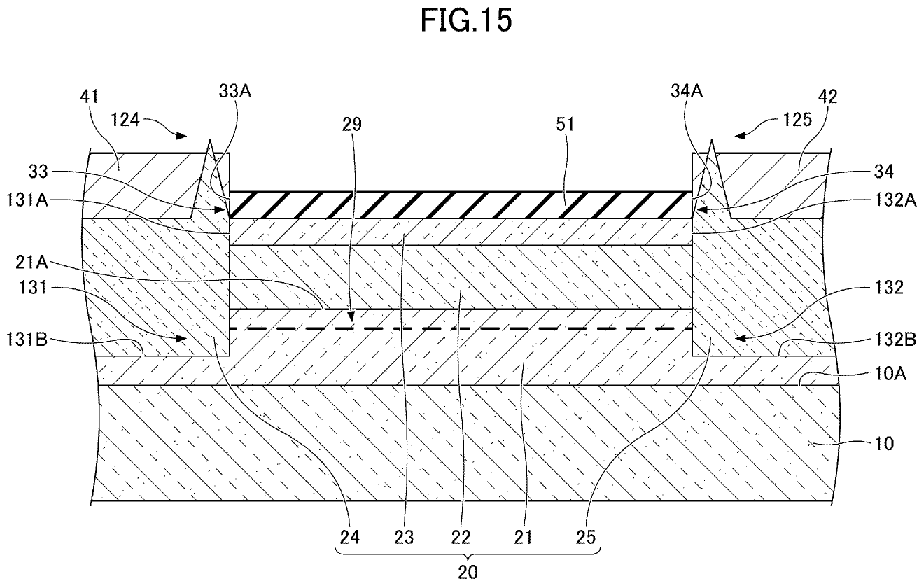

Next, as illustrated in FIG. 15, the source electrode 41 is formed on the source region 24, and the drain electrode 42 is formed on the drain region 25. The source electrode 41 and the drain electrode 42 can be formed by, for example, vapor deposition, a lift-off, and heat treatment for making an alloy. The source electrode 41 and the drain electrode 42 are in ohmic contact with the 2DEG 29, via the source region 24 and the drain region 25, respectively.

Thereafter, in the same manner as that in the first embodiment, the semiconductor device can be manufactured by performing the processes set after the formation of the seventh opening 52 in the electrically insulating layer 51.

However, in the reference example, as illustrated in FIG. 15, the source region 24 includes the abnormal growth portion 124, and the drain region 25 includes the abnormal growth portion 125. Thus, it is difficult to control the shapes of the source region 24 and the drain region 25 which are regrowth layers. When the source region 24 includes the abnormal growth portion 124, the contact resistance between the source electrode 41 and the source region 24 is likely to vary. Similarly, when the drain region 25 includes the abnormal growth portion 125, the contact resistance between the drain electrode 42 and the drain region 25 is likely to vary. For this reason, desired characteristics may not be obtained. In particular, when the abnormal growth portion 124 passes through the source electrode 41, or the abnormal growth portion 125 passes through the drain electrode 42, characteristics are likely to vary.

On the other hand, in the first embodiment, since the electrically insulating layer 51 has a portion that is the overhang for each of the first opening 31 and the second opening 32, the generation of the abnormal growth portions 124 and 125 is suppressed. Thus, the shapes of the source region 24 and the drain region 25 that are regrowth layers are easily controlled.

### First Modification of First Embodiment

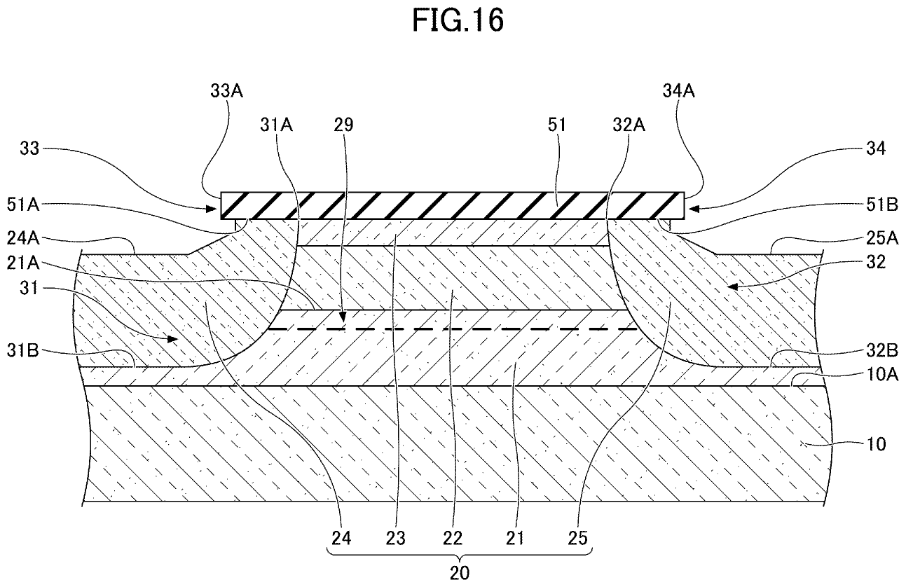

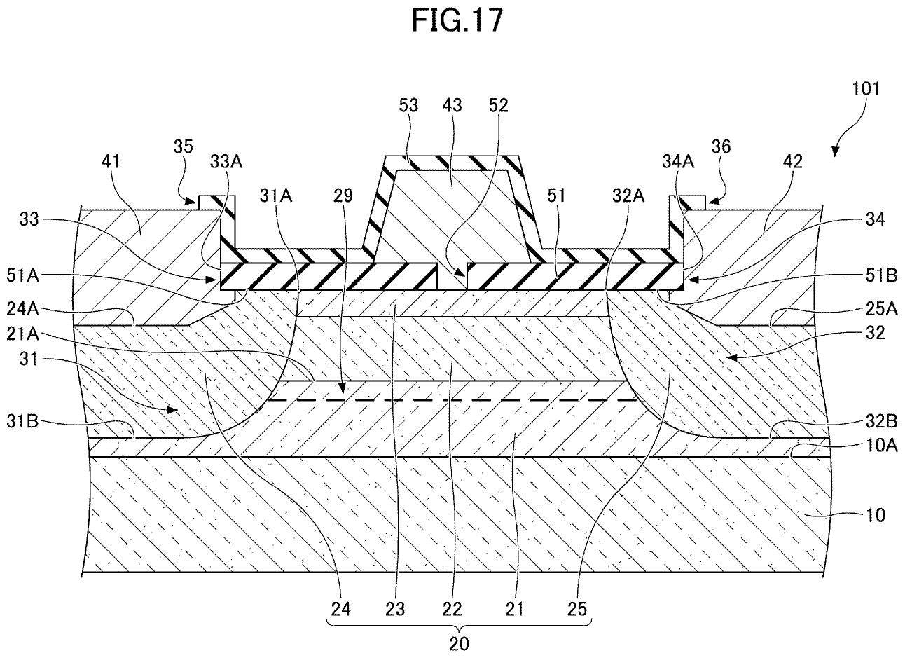

Next, a first modification of the first embodiment will be described. FIGS. 16 and 17 are cross-sectional views illustrating the semiconductor device according to the first modification of the first embodiment, the view being described for the method of manufacturing the semiconductor device according to the first modification of the first embodiment.

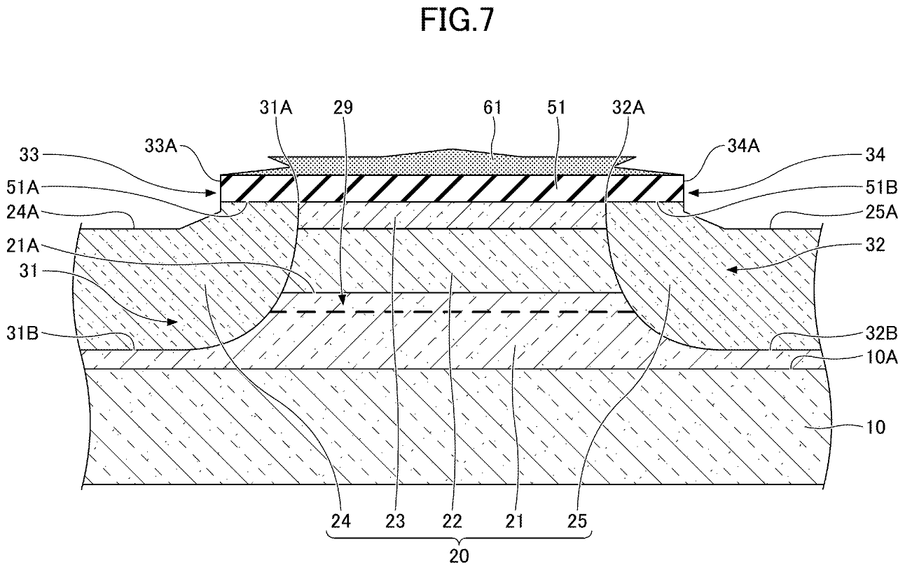

In the first modification of the first embodiment, processes to form the source region 24 and the drain region 25 are performed in the same manner as that in the first embodiment (see FIG. 7). Next, as illustrated in FIG. 16, the deposit 61 on the electrically insulating layer 51 is removed. The deposit 61 can be removed by using, for example, TMAH with a temperature of about 70° C. At this time, in the first modification, a portion of the source region 24 covering the lower surface 51A of the electrically insulating layer 51 is partially removed, and a portion of the drain region 25 covering the lower surface 51B of the electrically insulating layer 51 is partially removed. Accordingly, a portion of the lower surface 51A of the electrically insulating layer 51 is exposed to the first opening 31, and a portion of the lower surface 51B of the electrically insulating layer 51 is exposed to the second opening 32. In addition, the distance between the lower surface 51A of the electrically insulating layer 51 and the upper surface 24A of the source region 24 may be increased in the thickness direction of the substrate 10. The greatest distance of a given portion between the surface 51A of the electrically insulating layer 51 and the upper surface 24A of the source region 24 may be about 200 nm. Similarly, the distance between the lower surface 51B of the electrically insulating layer 51 and the upper surface 25A of the drain region 25 may be increased in the thickness direction of the substrate 10. The greatest distance of a given portion between the surface 51A of the electrically insulating layer 51 and the upper surface 25A of the drain region 25 may be about 100 nm.

Next, as illustrated in FIG. 17, the source electrode 41 is formed on the source region 24, and the drain electrode 42 is formed on the drain region 25. The source electrode 41 and the drain electrode 42 can be formed by, for example, filling, with metal, portions situated under the overhangs of the electrically insulating layer 51, and the filling is performed by vapor deposition, sputtering, or plating. Then, the lift-off and heat treatment for making an alloy are performed. The source electrode 41 and the drain electrode 42 are in ohmic contact with the 2DEG 29, via the source region 24 and the drain region 25, respectively.

Thereafter, a semiconductor device 101 according to the first modification of the first embodiment can be manufactured by performing the processes set after the formation of the seventh opening 52 in the electrically insulating layer 51, in the same manner as that in the first embodiment.

In the semiconductor device 101 according to the first modification of the first embodiment, a part of the source electrode 41 is in contact with a part of the lower surface 51A of the electrically insulating layer 51, and a part of the drain electrode 42 is in contact with a part of the lower surface 51B of the electrically insulating layer 51.

According to the first modification of the first embodiment, the same effect as that described in the first embodiment can be obtained.

### Second Modification of First Embodiment

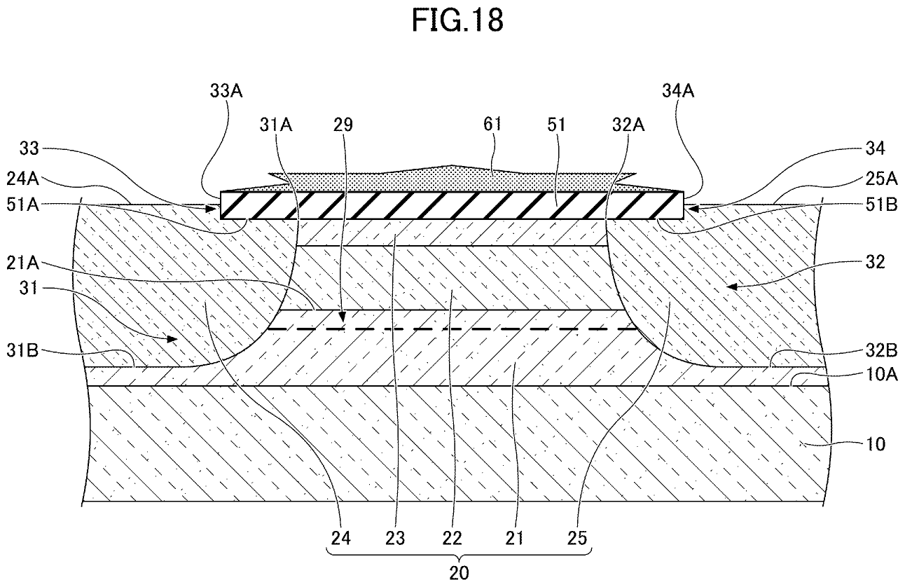

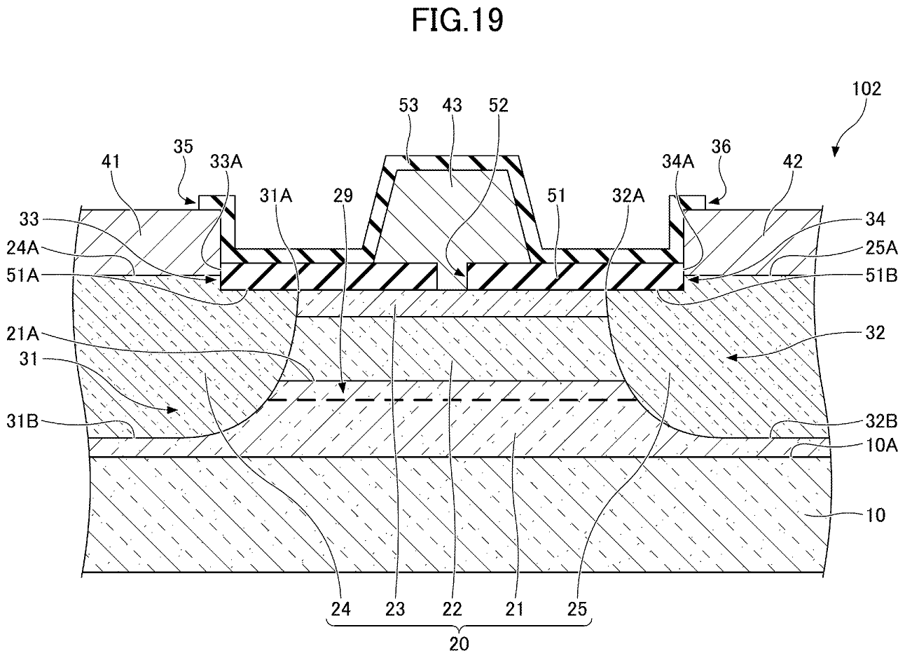

Next, a second modification of the first embodiment will be described. FIGS. 18 and 19 are cross-sectional views illustrating the semiconductor device according to the second modification of the first embodiment, the view being described for the method of manufacturing the semiconductor device.

In the second modification of the first embodiment, the first opening 31 and the second opening 32 are formed by photoelectrochemical etching, as in the first embodiment (see FIG. 3). Next, the resist mask 71 is removed to form the source region 24 in the first opening 31 and the drain region 25 in the second opening 32. At this time, in the second modification, as illustrated in FIG. 18, after the upper surface 24A of the source region 24 moves to be above the lower surface 51A of the electrically insulating layer 51, and the upper surface 25A of the drain region 25 moves to be above the lower surface 51B of the electrically insulating layer 51, the formation of the source region 24 and the drain region 25 is stopped.

Next, as illustrated in FIG. 19, the deposit 61 on the electrically insulating layer 51 is removed. The deposit 61 can be removed by using, for example, TMAH with a temperature of about 70° C. The source region 24 and the drain region 25 may be slightly etched by TMAH.

Thereafter, a semiconductor device 102 according to the second modification of the first embodiment can be manufactured by performing the processes set after the formation of the source electrode 41 and the drain electrode 42, in the same manner as that in the first embodiment.

In the semiconductor device 102 according to the second modification of the first embodiment, the upper surface 24A of the source region 24 is positioned above the lower surface 51A of the electrically insulating layer 51, and the upper surface 25A of the drain region 25 is positioned above the lower surface 51B of the electrically insulating layer 51.

According to the second modification of the first embodiment, the same effect as that described in the first embodiment can be obtained.

### Second Embodiment

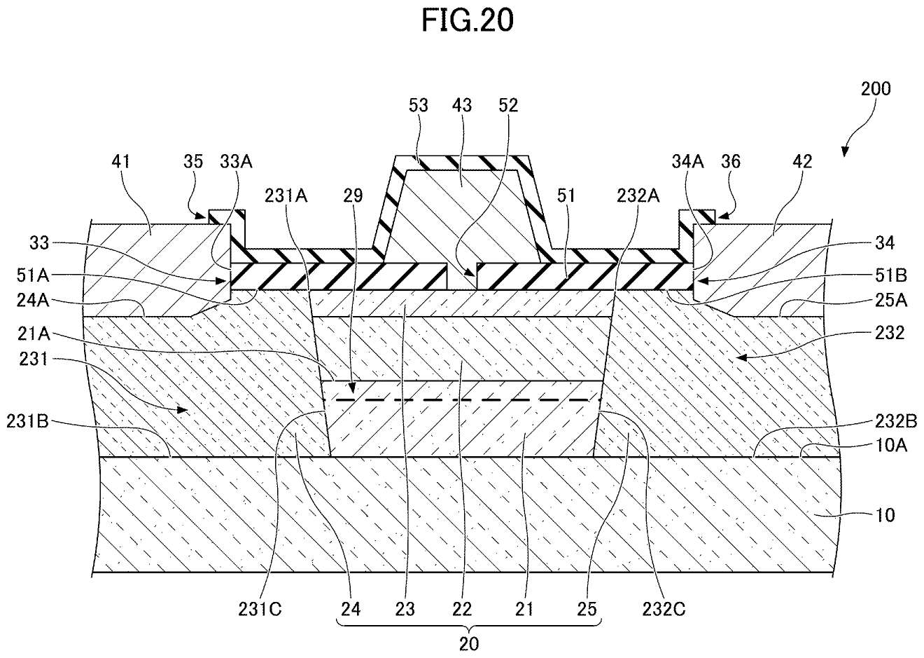

Next, a second embodiment will be described. FIG. 20 is a cross-sectional view illustrating the semiconductor device according to the second embodiment.

In a semiconductor device 200 according to the second embodiment, as illustrated in FIG. 20, in the layered structure 20, a first opening 231 for the source is formed instead of the first opening 31, and a second opening 232 for the drain is formed instead of second opening 32. The first opening 231 and the second opening 232 reach the substrate 10. Therefore, the first main surface 10A of the substrate 10 constitutes a bottom 231B of the first opening 231 and a bottom 232B of the second opening 232. The bottom 231B of the first opening 231 and the bottom 232B of the second opening 232 are positioned lower than the upper surface 21A of the electron transport layer 21, so as to be toward the substrate 10.

The first opening 231 has a first edge 231A near the second opening 232, and the second opening 232 has a second edge 232A near the first opening 231. In the plan view viewed in the direction perpendicular to the first main surface 10A, the first edge 231A of the first opening 231 is positioned closer to the second opening 232 than the third edge 33A of the third opening 33 is, and the second edge 232A of the second opening 232 is positioned closer to the first opening 231 than the fourth edge 34A of the fourth opening 34 is. In other words, the electrically insulating layer 51 has an overhang portion for each of the first opening 231 and the second opening 232. The electrically insulating layer 51 extends in the direction away from the second opening 232 such that a given end of the electrically insulating layer is disposed outside the first edge 231A of first opening 231. The electrically insulating layer 51 also extends in the direction away from the first opening 231 such that a given end of the electrically insulating layer is disposed outside the second edge 232A of the second opening 232.

The first opening 231 has a first side wall surface 231C toward the second opening 232, and the second opening 232 has a second side wall surface 232C toward the first opening 231. The first side wall surface 231C and the second side wall surface 232C are each inclined from a plane perpendicular to the first main surface 10A of the substrate 10. The first side wall surface 231C is inclined with respect to the plane perpendicular to the first main surface 10A of the substrate 10, so that the first opening 231 becomes wider as the first opening 231 is closer to the substrate 10. The second side wall surface 232C is inclined from the plane perpendicular to the first main surface 10A of the substrate 10, so that the second opening 232 becomes wider as the second opening is closer to the substrate 10. Accordingly, the portion, between the first opening 231 and the second opening 232, of the electron transport layer 21, the electron supply layer 22, and the cap layer 23 has a shape tapered toward the substrate 10 in cross-section.

Other configurations are the same as those of the first embodiment.

In the semiconductor device 200, the 2DEG 29 is present near the upper surface 21A of the electron transport layer 21. The source electrode 41 is in ohmic contact with the 2DEG 29, through the source region 24, and the drain electrode 42 is in ohmic contact with the 2DEG 29, through the drain region 25. Therefore, the presence of the source region 24 and the drain region 25 can reduce the contact resistance, which is the sum of the resistance between the source electrode 41 and the 2DEG 29 and the resistance between the drain electrode 42 and the 2DEG 29.

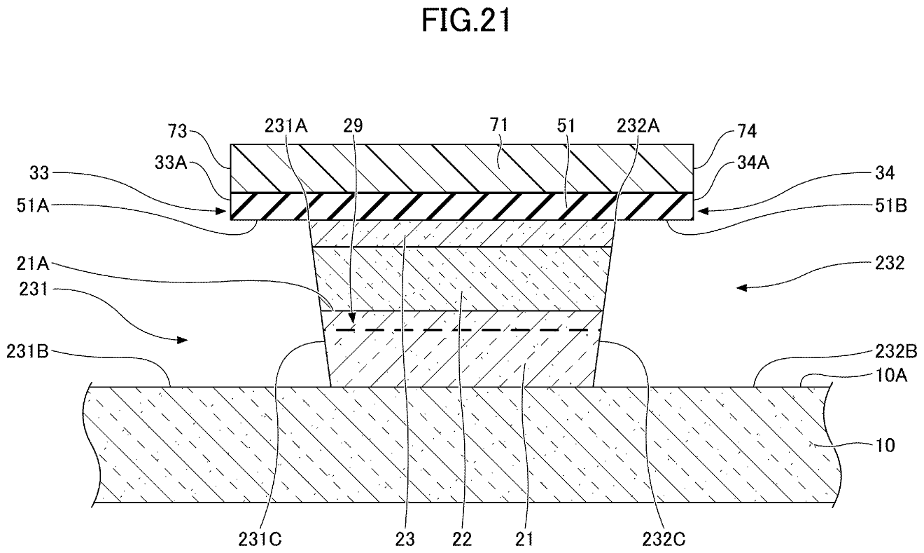

Next, the method of manufacturing the semiconductor device 200 according to the second embodiment will be described. FIGS. 21 to 23 are cross-sectional views illustrating the semiconductor device according to the second embodiment, the view being described for the method of manufacturing the semiconductor device.

First, as illustrated in FIG. 21, processing in which the resist mask 71 is formed is performed in the same manner as that in the first embodiment. Next, the third opening 33 and the fourth opening 34 are formed in the electrically insulating layer 51 by RIE. Next, by RIE, the first opening 231 is formed in the electron transport layer 21, the electron supply layer 22, and the cap layer 23, through the opening 73 and the third opening 33, and further, the second opening 232 is formed through the opening 74 and the fourth opening 34. Reactive gas containing chlorine (Cl) is used to etch the electron transport layer 21, the electron supply layer 22, and the cap layer 23. In this embodiment, unlike in the reference example, the first opening 231 and the second opening 232 are formed so as to reach the substrate 10. In addition, even when the first main surface 10A of the substrate 10 is exposed, the supply of the reactive gas is continued such that the supply of the reactive gas is not stopped immediately after the exposing of the first main surface. The substrate 10 is not etched even if the supply of the reactive gas is continued. Thus, the concentration of the reactive gas is increased in the vicinity of the first main surface 10A. As a result, etching of the electron transport layer 21, the electron supply layer 22, and the cap layer 23 is performed in the direction parallel to the first main surface 10A (lateral direction). Therefore, the electrically insulating layer 51 extends in the direction away from the second opening 232 such that a given end of the electrically insulating layer is disposed outside the first edge 231A of the first opening 231. Also, the electrically insulating layer 51 extends in the direction away from the first opening 231 such that a given end of the electrically insulating layer is disposed outside the second edge 232A of the second opening 232. In other words, the electrically insulating layer 51 has a portion serving as the overhang for each of the first opening 231 and the second opening 232.

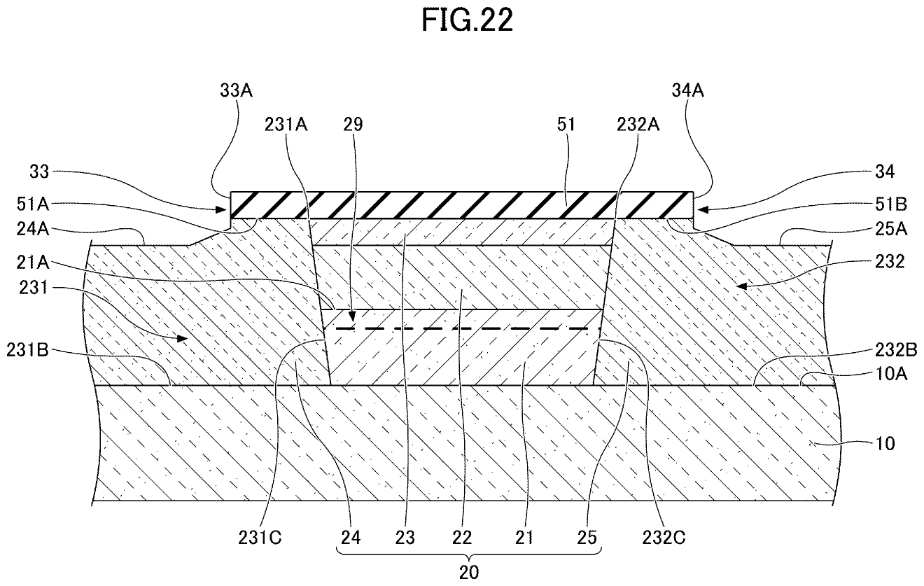

Next, as illustrated in FIG. 22, similarly to the first embodiment, the resist mask 71 is removed, and thus the source region 24 is formed in the first opening 231, and the drain region 25 is formed in the second opening 232. Then, as in the first embodiment, the deposit 61 generated when the source region 24 and the drain region 25 are formed is removed.

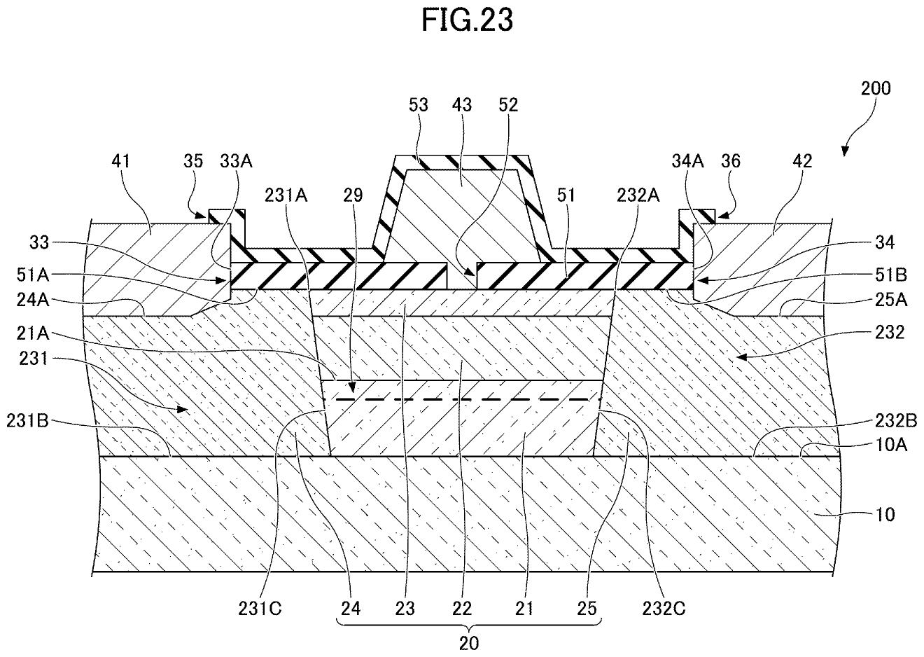

Next, as illustrated in FIG. 23, the source electrode 41 is formed on the source region 24, and the drain electrode 42 is formed on the drain region 25. The source electrode 41 and the drain electrode 42 can be formed by, for example, vapor deposition, a lift-off, and heat treatment for making an alloy. The source electrode 41 and the drain electrode 42 are in ohmic contact with the 2DEG 29, via the source region 24 and the drain region 25, respectively.

Thereafter, the semiconductor device 200 according to the second embodiment can be manufactured by performing the processes set after the formation of the seventh opening 52 in the electrically insulating layer 51, in the same manner as in the first embodiment.

According to the second embodiment, the same effect as that in the first embodiment can be obtained.

In the second embodiment, a material having resistance to reactive gas containing chlorine is used as the material of the substrate 10. Thus, the substrate 10 may be a sapphire substrate.

Although the embodiments have been described above in detail, the present invention is not limited to the specific embodiments, and various modifications and changes can be made within the scope described in the claims.

What is claimed is:

1. A semiconductor device comprising:
a substrate including a first main surface;
a semiconductor layer provided on the first main surface of the substrate, the semiconductor layer including
an electron transport layer provided on the substrate, the electron transport layer including a first upper surface,
an electron supply layer provided on the electron transport layer,
a source region containing a first electrically conductive impurity, the source region being provided in a first opening, and
a drain region containing the first electrically conductive impurity, the drain region being provided in a second opening;
an electrically insulating layer provided on the semiconductor layer;
a source electrode and a drain electrode, each of the source electrode and the drain electrode being provided on the semiconductor layer, the source electrode being provided on the source region, and the drain electrode being provided on the drain region; and
a gate electrode provided on the electrically insulating layer, wherein
the first opening and the second opening are each formed in the electron supply layer and the electron transport layer, the first opening having a first edge toward the second opening, the second opening having a second edge toward the first opening,
a bottom of the first opening and a bottom of the second opening are positioned lower than the first upper surface, so as to be toward the substrate,
a third opening connected to the first opening, and a fourth opening connected to the second opening are each formed in the electrically insulating layer, the third opening having a third edge toward the fourth opening, and the fourth opening having a fourth edge toward the third opening, and
in a plan view viewed in a direction perpendicular to the first main surface,
the first edge of the first opening is positioned closer to the second opening than the third edge of the third opening is,
the second edge of the second opening is positioned closer to the first opening than the fourth edge of the fourth opening is,
a portion of the source region overlaps the electrically insulating layer, and
a portion of the drain region overlaps the electrically insulating layer.

2. The semiconductor device according to claim 1, wherein in the plan view viewed in the direction perpendicular to the first main surface,
a distance between the first edge and the third edge is greater than or equal to 0.2 μm and less than or equal to 1.5 μm, and
a distance between the second edge and the fourth edge is greater than or equal to 0.2 μm and less than or equal to 1.5 μm.

3. The semiconductor device according to claim 1, wherein
a portion of an upper surface of the source region is in contact with a portion of a lower surface of the electrically insulating layer, and
a portion of an upper surface of the drain region is in contact with another portion of the lower surface of the electrically insulating layer.

4. The semiconductor device according to claim 1, wherein the gate electrode is in Schottky contact with the semiconductor layer.

5. A method of manufacturing a semiconductor device, the method comprising:
forming an electron transport layer including a first upper surface, the electron transport being situated on a first main surface of a substrate;
forming an electron supply layer on the electron transport layer;
forming an electrically insulating layer above the electron supply layer;
forming a third opening and a fourth opening in the electrically insulating layer, the third opening having a third edge toward the fourth opening, and the fourth opening having a fourth edge toward the third opening;
forming (i) a first opening connected to the third opening and (ii) a second opening connected to the fourth opening, each of the first opening and the second opening being formed in the electron supply layer and the electron transport laver, the first opening having a first edge toward the second opening, and the second opening having a second edge toward the first opening;
forming a source region containing a first electrically conductive impurity in the first opening and forming a drain region containing the first electrically conductive impurity in the second opening;
forming a source electrode on the source region and forming a drain electrode on the drain region; and
forming a gate electrode on the electrically insulating layer, wherein
a bottom of the first opening and a bottom of the second opening are positioned lower than the first upper surface, so as to be toward the substrate,
in a plan view viewed in a direction perpendicular to the first main surface,
the first edge of the first opening is positioned closer to the second opening than the third edge of the third opening is, and the second edge of the second opening is positioned closer to the first opening than the fourth edge of the fourth opening is,
a portion of the source region overlaps the electrically insulating layer, and
a portion of the drain region overlaps the electrically insulating layer.

6. The method of manufacturing the semiconductor device according to claim 5, further comprising: forming a mask on the electrically insulating layer, between the forming of the electrically insulating layer and the forming of the third opening and the fourth opening, wherein
the forming of the third opening and the fourth opening includes performing reactive ion etching of the electrically insulating layer, by using the mask, and
the forming of the first opening and the second opening includes performing photoelectrochemical etching of the electron supply layer and the electron transport layer, by using the mask.

7. The method of manufacturing the semiconductor device according to claim 5, the method further comprising: forming a mask on the electrically insulating layer, between the forming of the electrically insulating layer and the forming of the third opening and the fourth opening, wherein
the forming of the third opening and the fourth opening includes performing reactive ion etching of the electrically insulating layer, by using the mask,
the forming of the first opening and the second opening includes performing reactive ion etching of the electron supply layer and the electron transport laver, by using the mask, and
in the reactive ion etching of the electron supply layer and the electron transport layer, supply of a reactive gas is continued after the first main surface of the substrate is exposed.
